(19) United States
(12) Patent Application Publication
(10) Pub. No.: US 2010/0282598 A1
(43) Pub. Date: Nov. 11, 2010

(54) Method for controlling a reactive-high-power pulsed magnetron sputter process and corresponding device

(75) Inventors: Florian Ruske, Braunschweig (DE); Volker Sittinger, Braunschweig (DE); Bernd Szyszka, Braunschweig (DE)

Correspondence Address: MARSHALL & MELHORN, LLC, FOUR SEAGATE - EIGHTH FLOOR, TOLEDO, OH, 43604, US

(73) Assignee: Fraunhofer-Gesellschaft Zur Foerderung Der Angewan dten Forschung E.V., Munich (DE)

(21) Appl. No.: 12/308,589

(22) PCT Filed: Jun. 20, 2007
(86) PCT No.: PCT/EP2007/005442

§ 371 Date: Jul. 12, 2010

(30) Foreign Application Priority Data
Jun. 20, 2006 (DE) 10 2006 028 303.1
Dec. 22, 2006 (DE) 10 2006 061 324.4

(51) Int. Cl. C23C 14/34

(52) U.S. Cl. 204/192.13; 204/298.03

(57) ABSTRACT

The invention relates to the control of a reactive high-power pulsed sputter process. The invention particularly relates to a method for controlling a process of the aforementioned kind, wherein a controlled variable is measured and an adjustable variable is modified based on the measured controlled variable in order to adjust the controlled variable to a predetermined setting value. The method according to the invention is characterised by modifying the discharge capacity by varying the pulse frequency of the discharge.

The present invention relates to a method for controlling a reactive high-power pulse magnetron sputtering process and a device for this purpose.

The method enables the stabilisation of the reactive sputtering process so that layers with the desired morphology and phase composition can be deposited on a substrate.

Plasma sputtering is an established technology for coating substrates, in particular with ceramic or other multicomponent functional layers. A reactive sputtering process is hereby based on the sputtering of metallic targets in a reactive gas atmosphere so that a compound comprising the target material and one of more components of the process gas is deposited on the substrate.

An essential problem with reactive sputtering results however from the fact that the reactive gas partial pressure cannot constantly be altered. The parameter scope falls therefore into the defined domains “compound mode”, with high reactive gas partial pressure and a target surface covered completely with reaction products and also stoichiometric layers on the substrate, and a “metallic mode” with a low reactive gas partial pressure in the sputtering chamber, an extensively metallic target surface and the growth of metallic layers on the substrate. Between these domains, a constant transition is in general impossible, rather there result unstable process states, the occurrence of which is sketched in the following. Reference is thereby made for example to the reactive gas O₂ but the cited mechanisms also apply for sputtering in N₂, CHₓ and the like.

At the beginning of the magnetron sputtering, reactive gas is added to the sputtering chamber. Thereupon, growth and etching processes which compete on the target surface take place. In the case of a low O₂ partial pressure, the rate for the growth of the oxide covering is low so that the etching process predominates due to the sputtering removal of the oxide layer. The target surface therefore remains in total metallic. This state is stable since the target operates as an efficient getter pump, the overall pumping capacity of which is often a multiple of the pumping capacity of the turbo pump which is actually used for the evacuation.

If the reactive gas partial pressure is increased, then an oxide layer grows on the target surface at a somewhat higher rate. In the case of low ion flow densities and hence a low etching rate, the growth process then predominates. In this way, target regions which are covered with reaction products and are also termed “contaminated target regions” are produced.

Relative to the metal, these contaminated target regions always have a lower sputtering yield so that overall less target material is sputtered. This leads to a reduction in the material removal on the target, a reduction in the target pumping capacity, and hence to a further increase in the reactive gas partial pressure.

As soon as the reactive gas partial pressure exceeds a critical value, the result consequently is a self-reinforcing effect since the increase in the reactive gas partial pressure results in a reduction in the pumping capacity of the target getter pump, from which in turn an increase in the reactive gas partial pressure results. This instability characterises the transition from metallic mode into the compound mode.

The stabilisation in particular of the non-constant transition between these two states is technically of great interest since, on the one hand, the growth rate in the compound mode caused by the low sputtering yield is only low, on the other hand, the layers in the compound mode grow with reactive gas excess, as a consequence of which unfavourable layer properties result. In the transition range, not only stoichiometric layers are hence deposited at higher rates than in the “compound mode” but also layer properties are achieved which are not achievable in the other ranges. The deposition of Al-doped zinc oxide may be cited as an example: only in the case of deposition in the transition range does the material have both high optical transparency and high electrical conductivity. On the other hand, the reactive gas partial pressure is in general too low in the metallic mode so that then absorbing substoichiometric compounds grow.

The desired stoichiometric layers can however be deposited at a high rate when the process is operated precisely in the unstable transition range which is also termed “transition mode”. The stabilisation of this non-constant transition state “transition mode” is possible by means of control circuits which take into account the dynamic behaviour of the sources and which thus can maintain the unstable operating points which are technically of interest.

Between the two deposition regimes (compound mode and metallic mode), no constant transition is hence possible and no stable operating points exist for stabilisation of average reactive gas partial pressures. In order nevertheless to be able to operate the process in the transition range of technical interest, active control systems are required (active process control) in which an external adjustable variable is adapted continuously according to the specification of a measured process parameter (controlled variable). It is hereby known, for stabilisation of the process, to undertake adaptation of the electrical discharge parameters, target voltage or target current, according to the specification of a primary process parameter, such as e.g. the partial pressure of the reactive gas components or the plasma emission. Hence in this case the electrical discharge parameters, cathode voltage or cathode current are used as adjustable variable. It is also known to use the reactive gas flow itself as adjustable variable. Both systems are widely used.

In the case of the measured process parameter, various solutions are likewise possible. Reactive gas partial pressures can be measured directly with mass spectrometers, in the case of oxygen also with a λ probe. The total pressure in the chamber can also serve as input variable. A further possibility is represented by the measurement of the optical emission of the plasma. Finally, also a measurement of the cathode voltage for different materials is a suitable solution. In plasmas operated with alternating fields, the analysis of Fourier transforms of the voltage- and current signal of the discharge achieves the objective. Thus for example with the optical emission spectrometer, the emission of the metal atoms in the plasma can be recorded; the reactive gas flow is varied in order to equalise deviations of the emission intensity from the reference value. In another example, the oxygen partial pressure during deposition of a metal oxide is observed with a λ probe; in the case of deviations from the reference value, the discharge power of the generator is adapted.

Magnetron sputtering represents a known, large-industrial, readily convertible method for depositing layers of high quality on the most varied of substrates. In particular, the method is suitable for depositing ceramic or other multicomponent layers.

A relatively new variant of magnetron sputtering is the so-called high-power pulse magnetron sputtering (HPPMS or HIPIMS), see also D. J. Christie, Journal of Vacuum Science and Technology A 23 (2005), pages 330 to 335 and Kouznetsov, V.; Macak, K.; Schneider J. M.; Helmersson, U.; Petrov, I.: A novel pulsed magnetron sputter technique utilising very high target power densities in: Surface and Coatings Technology 122 (1999), pp. 290-3. The plasma is hereby excited by individual pulses of high-power density. The plasma itself is built up by periodic discharging of a capacitor bank. A pulsed process is of concern in which the power density on the target reaches approx. 30 to 100 times the values which are normal during DC operation. Power densities far above 1 kW/cm² are possible. Under such conditions, the magnetron discharge is operated in the transition to arc discharge. Consequently, the result is increased ionisation of the sputtered target material. For sputtering of metals, already ionisation degrees of more than 80% relative to values of less than 1% for conventional operation were achieved (D. J. Christie et al., 48^{th} SVC Proceedings (2005)).

Various works on reactive sputtering by means of HPPMS are already known from the state of the art. When using an active control, the reactive gas flow has hereby always been used as adjustable variable for stabilising the discharge in the transition range (see for example D. A. Clocker et al., 47^{th} SVC Proceedings (2004), p. 183 and W. D. Sproul et al., 47^{th} SVC Proceedings (2004), p. 96 ff.). The gas flow control hereby has the advantage that any hardware already present can be used without new software requiring to be written (no new control need therefore be constructed, rather a plant with a functioning gas flow control is resorted to). The adjustment of the operating point by varying the reactive gas flow has the main disadvantage however of a comparatively low speed of the control. In general, adaptation of the gas flow only with a short delay in the process is noticeable. In addition, the devices required for a rapid gas flow control, such as e.g. suitable gas distributors and mass flow controllers, are expensive.

It is hence the object of the invention to make available a method and a device for stabilisation of reactive processes during high-power pulse sputtering, with which stabilisation of the operating point is possible in a simple, fast and uncomplicated manner and without changing the process characteristic.

The basic concept of the proposal for the solution of the present invention is to adapt the discharge power during high-power pulse sputtering by means of a control loop (as described subsequently), instead of the use of the reactive gas flow as adjustable variable for stabilisation of the discharge as in the state of the art.

The basic problem hereby is that, with variation of the power density within the individual discharge pulses, the process characteristic is greatly altered and the ionisation rate hence changes markedly. Stabilisation of a reactive high-power pulse sputtering process can therefore not be implemented by adapting the power per pulse. This problem is resolved by adapting the frequency of the discharge whilst maintaining the form of the individual discharge pulses. As a result, the average power is varied without the result being a change in the process characteristic.

In the case of sufficiently high pulse frequencies, the discharge at the desired operating point can hence be stabilised.

The frequency is sufficiently high if no appreciable change in the target state takes place in the intervals between two pulses. According to the material, the frequency should hereby be above 20 Hz, preferably even above 100 Hz. In the case of higher frequencies, better process control must be expected, in the case of high-power sputtering the frequency is limited upwardly by the thermal loadabilty of the target.

The adaptation according to the invention of the discharge power by means of frequency variation is thereby based on the following considerations:

The average power applied to the target for a pulsed plasma discharge is calculated as follows:

P̅=f*Wₚᵤₗₛ (1)

f thereby designates the frequency of the discharge and Wₚᵤₗₛ the energy per pulse. There is produced from the current- and voltage course within one pulse:

$${W}_{Puls} = {\int }_{τ} U ( t ) * I ( t ) d t \qquad ( 2 )$$

The integration must thereby be effected over one pulse duration. The product comprising pulse duration T and frequency f is also termed “duty cycle q”. In order now to produce a control of a reactive process for high-power pulse sputtering by varying the power, either the energy per pulse Wₚᵤₗₛ or the frequency f can basically be varied according to formula (1). In the case of high-power pulse sputtering, a significant change in the discharge characteristic can be observed however when changing the power per pulse. In the case of very high power densities the result is an increased ionisation of the sputtered material and hence a greatly altered particle flow to the substrate. A change in energy per pulse (or power per pulse) would hence constantly alter the ionisation, as a result of which the aim of increased process stability even over long periods of time would be counteracted.

Upon varying the frequency or the duty cycle, the form of the individual pulses and hence the composition of the sputtered species remains independent of the average power P. This frequency variation according to the invention enables process stabilisation by power adaptation without variation of the discharge characteristic.

According to the invention, a method for controlling a reactive high-power pulse sputtering process (in particular a magnetron sputtering process) is hence made available, in which, by means of a control circuit or a control loop as adjustable variable, the discharge power is adapted constantly continuously in that the pulse frequency of the discharge is varied.

In an advantageous variant (see subsequent embodiment), this can take place in that a reference value process curve is recorded and stored in that, for a plurality of reference values of the controlled variable, respectively one value to be adjusted for the adjustable variable is determined and stored and the adjustment of the controlled variable to the predetermined reference value is effected based on the previously stored reference value process curve. The predetermined reference value or operating point can be chosen then advantageously such that the reactive high-power pulse sputtering process is stabilised in the unstable transition range. There can be used as controlled variable in advantageous embodiment variants of the method according to the invention, the reactive gas partial pressure, the target current or the target voltage or, as is also known already from the state of the art, the optical emission of the plasma or a controlled variable derived from a harmonic analysis of the voltage- and/or current signal of the discharge.

According to the invention, a method and a device for controlling a reactive high-power pulse sputtering process is hence made available, which is characterised in that, based on a suitable measurement of the controlled variable, the discharge power is adapted by adapting the pulse frequency (or as an alternative thereto the duty cycle) in order to operate the discharge at the desired operating point (which is then chosen preferably in the unstable transition range or transition mode).

The present invention hence makes it possible to adjust the desired operating point in a simple manner via rapid and uncomplicated adaptation of the discharge power via the frequency of the discharge without the process characteristic being influenced disadvantageously. Hence the present invention makes it possible in a simple manner to stabilise a reactive high-power pulse sputtering process so that layers with the desired morphology and phase composition can be deposited on the substrate in a simple manner.

Firstly as a consequence thereof, the use of fully reactive processes of materials of a complex structure for the field of PVD methods with high ionisation degrees is made possible. In particular, the nucleation processes of thin films (such as for example ZnO:Al thin films) can be improved with methods according to the invention and hence also the approaches for highly qualitative crystal growth can be applied to films of a lesser thickness. Hence thin films with an improved crystallinity and with an improved specific electrical resistance (for example also below 400 μΩcm) can be produced. With the method according to the invention, also conductive and transparent TCO thin films in particular can be deposited. The said thin films (for example in the thickness range of 100 to 150 nm) can be used in particular advantageously for flat screens. The deposition on substrates at a low substrate temperature—in addition to deposition of thin films with thicknesses of less than 400 nm—is thereby possible with the method according to the invention in a particularly advantageous manner.

A method according to the invention or a device according to the invention can be configured or used as described in the subsequent example.

An example of a process according to the invention is described subsequently. Reactive HPPMS sputtering of aluminium-doped zinc oxide layers is investigated. For this purpose, a coating plant with a cathode of a dimension of 750×88 mm² is used. The cathode is made of zinc with an aluminium proportion of 1.0% by weight. Argon is admitted into the chamber as operating gas and oxygen as reactive gas. A discharge is struck by means of the generator described in Christie, D. J.; Tomasel, F.; Sproul, W. D.; Carter, D. C.: Power supply with arc handling for high peak power magnetron sputtering in: Journal of Vacuum Science and Technology A 22 (2004), pp. 1415-9, the charge voltage for the capacitors is 1000 V.

A λ probe is used in the present case for measurement of the reactive gas partial pressure or oxygen partial pressure. The discharge of the capacitors of the capacitor bank takes place by means of a frequency generator so that the frequency of the discharge can be adjusted easily.

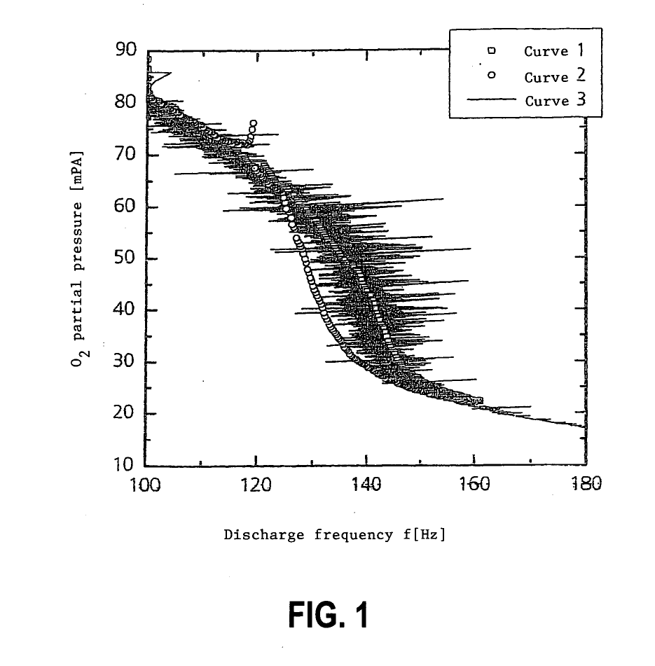

Firstly a reference value process curve is recorded in that the oxygen partial pressure is recorded as a function of the discharge frequency f. In this respect, curve 1 in FIG. 1 shows the course of the oxygen partial pressure (ordinate) for rising discharge frequencies f (abscissa) and curve 2 the corresponding course for falling discharge frequencies f. It is detected that no unequivocal relationship between the discharge frequency f (as adjustable variable to be adjusted or altered) and the oxygen partial pressure (as measured controlled variable) exists here but instead that different curves are produced according to the previous history of the discharge. This effect is already known as hysteresis in the case of the reactive sputtering process. FIG. 1 shows the hysteresis of the reactive sputtering process of aluminium-doped zinc targets with the addition of oxygen with variation of the discharge power and also operating points stabilised by means of the control.

By means of a control circuit, the discharge is now stabilised according to the invention at various oxygen partial pressures. The control circuit keeps the deviation of the measured oxygen partial pressure (measured controlled variable) from its reference value small for this purpose in that the discharge frequency, as described subsequently more precisely, is altered with inclusion of a reference value process curve (S-curve).

In order to produce the reference value curve (S-curve), the latter is recorded in that the reference value of the oxygen partial pressure for the control loop is increased continuously. The discharge frequency f which is required for stabilisation of the oxygen partial pressure at a reference value is stored in a memory of the device. The curve 3 of FIG. 1 shows the thus obtained process curve. As can be detected, a further range of oxygen partial pressures is stabilised. Above all in the unstable transition range of interest, no great deviations from the reference value can be established. Merely the frequencies f required for stabilisation of the operating point can vary, as FIG. 1 shows. Stable process control is nevertheless possible at all operating points.

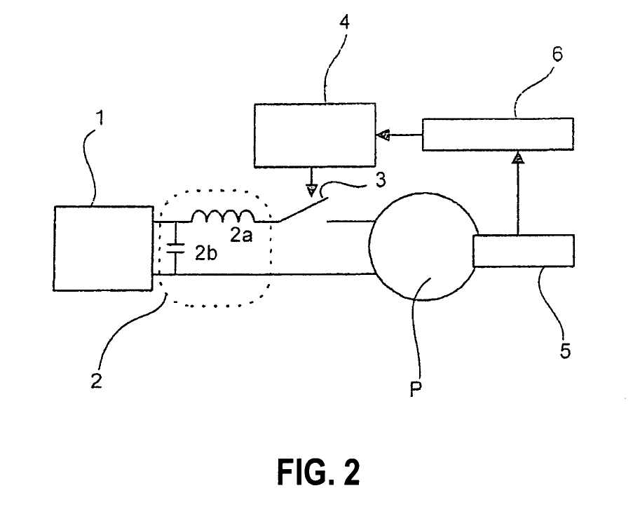

FIG. 2 shows the basic schematic construction for a plant with which the method according to the invention can be implemented. An oscillating circuit 2 is hereby connected to the power unit. This oscillating circuit comprises a capacitor 2b and a coil 2a. With the help of the power unit, a defined voltage U_{c} can be applied to the capacitor 2b (charging of the capacitor). The capacitor 2b can then be discharged into the plasma via the coil 2a of the oscillating circuit with the help of a switch 3. There applies for the energy stored in the capacitor: Eₚᵤₗₛ=0.5*C*U_{c}² (c=capacitance of the capacitor 2b, U_{c}=load voltage of the capacitor). The discharge of this energy takes place as described into the plasma B due to the inductivity 2a. The oxygen partial pressure is determined by a lambda probe 5. With the help of the value of the oxygen partial pressure determined with the lambda probe, the frequency of the frequency generator 4 is varied, as already described with the help of the PID control 6, hence the pulse frequency of the discharge is varied.

In the described case, a Zn/Al cathode with an aluminium concentration of 1.0% by weight is sputtered in an atmosphere comprising oxygen and argon. The gas flow rates are hereby kept constant advantageously during the coating process. The argon flow rate and the pump speeds are adapted to a total pressure between 650 and 800 mPa. The oxygen flow rate is selected such that both the metallic mode and the oxide mode can be stabilised for a given defined target voltage without further alterations being required (see subsequently). The deposition can hereby be implemented on unheated substrates (at room temperature) just as on substrates which are heated to 200° C. There can be used for example as substrate. Advantageously values between 700 V and 1200 V can be used as target voltage. The oxygen partial pressure can be adjusted for example to a constant value between 32.5 and 45 mPa. As described, both a deposition at room temperature and for example with heated substrates (200° C. substrate temperature) is possible. During deposition at a substrate temperature of 200° C., also higher oxygen partial pressures, e.g. with values between 45 and 70 mPa can advantageously be set.

The following parameters were used for the above-described reference value process curve (S-curve):

| Process | HPPMS excitation at a load voltage of 1000 V, | | |
|---|---|---|---|
| | PK750 cathode | | |
| System parameter | Target-substrate spacing | d_{ST} | 90 mm |
| | Target material | | ZnO:Al |
| | | | (1.0% by wt.) |
| | Gas flow | q_{Ar} | 2 × 50 sccm |
| | | q_{O2} | 45 sccm |
| Process parameter | Substrate temperature | Tₛ | 200° C. |
| | Total pressure | pₜₒₜ | 650-750 mPa |

1-11. (canceled)

12. A method for controlling a reactive high-power pulse sputtering process, in which a controlled variable is measured and an adjustable variable based on the measured controlled variable is altered in order to adjust the controlled variable to a predetermined reference value, wherein the discharge power as adjustable variable is altered in that the pulse frequency of the discharge is varied whilst maintaining the form of the individual discharge pulses.

13. The method according to claim 12, wherein a reference value process curve is recorded and stored in that, for a plurality of reference values of the controlled variable, respectively one value to be adjusted for the adjustable variable is determined and stored, and in that the adjustment of the controlled variable to the predetermined reference value is effected based on the reference value process curve.

14. The method according to claim 12, wherein the predetermined reference value is chosen such that the reactive high-power pulse sputtering process is stabilized in the unstable transition range.

15. The method according to claim 12, wherein there is used as controlled variable, the reactive gas partial pressure, the target current, the target voltage, the optical emission of the plasma, the total pressure in the sputtering chamber or a controlled variable derived from a harmonic analysis of the voltage- and/or current signal of the discharge.

16. The method according to claim 15, wherein the reactive gas partial pressure is measured by means of a lambda probe or by means of a mass spectrometer.

17. The method according to claim 12, wherein the pulse frequency of the discharge is varied with the help of a frequency generator.

18. The method according to claim 12, wherein the control loop is configured as proportional control, differential control or integral control.

19. The method according to claim 12, wherein the control takes place with oxygen, nitrogen or a mixture thereof as reactive gas.

20. The method according to claim 12, wherein a reactive high-power pulse magnetron sputtering process is controlled.

21. A device for reactive high-power pulse sputtering having
a sputtering chamber,
a cathode on which the target to be atomized is disposed,
a capacitor bank which has at least one capacitor, by means of the periodic
discharge of which the plasma can be built up, and a control unit with which a controlled variable is measurable and an adjustable variable based on the measured controlled variable can be altered in order to adjust the controlled variable to a predetermined reference value, the device being configured for variation of the pulse frequency of the discharge of the capacitors of the capacitor bank whilst maintaining the form of the individual discharge pulses in order to alter the discharge power as adjustable variable.

22. The device according to claim 21, further comprising a frequency generator which is coupled to the capacitor bank and with which the pulse frequency of the discharge can be varied by control of the discharge characteristic of the capacitors of the capacitor bank.
